(19) United States
(12) Patent Application Publication
(10) Pub. No.: US 2026/0283012 A1
(43) Pub. Date: Sep. 17, 2026

(54) Semiconductor Device and Method of Making Using Ultraviolet Light for Photonics Protection

(71) Applicant: STATS ChipPAC Pte. Ltd., Singapore (SG)

(72) Inventors: Yi Xiang Jasper Tay, Singapore (SG); Swain Hong Alfred Yeo, Singapore (SG); Chee Meng Law, Johor Bahru (MY); Junyi Zeng, Singapore (SG)

(73) Assignee: STATS ChipPAC Pte. Ltd., Singapore (SG)

(21) Appl. No.: 19/079,288

(22) Filed: Mar. 13, 2025

(51) Int. Cl. H01L 25/16; G02B 6/42; H01L 21/68; H01L 21/683; H01L 23/00; H01L 23/13; H01L 23/29; H01L 23/498; H01L 25/00; H01L 25/18

(52) U.S. Cl. CPC H10W 90/00; G02B 6/4249; G02B 6/4255; H10P 72/57; H10P 72/7402; H10W 70/635; H10W 70/68; H10W 74/47; H10W 90/701; H10W 72/07335; H10W 72/242; H10W 72/244; H10W 74/15; H10W 90/724; H10W 90/735

(57) ABSTRACT

A semiconductor device is manufactured using a transparent carrier. A build-up interconnect structure is formed on the transparent carrier. An opening is formed through the build-up interconnect structure. A semiconductor die is disposed over the build-up interconnect structure with a photonic circuit of the semiconductor die aligned to the opening. An ultraviolet (UV) lamp is disposed over the carrier opposite the semiconductor die. The UV lamp emits a UV light that impinges on the photonic circuit through the carrier and opening. An underfill is deposited between the build-up interconnect structure and semiconductor die while the UV lamp emits the UV light. The underfill is a photobond acrylate. The UV light cures the underfill before the underfill flows into the opening.

### FIELD OF THE INVENTION

The present invention relates in general to semiconductor devices and, more particularly, to semiconductor devices and methods of making using ultraviolet light for photonics protection.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Photonic semiconductor devices, which are capable of transmitting or receiving signals via light, are becoming more and more common. Photonic semiconductor die are packaged with an optical window or grating area to allow optical signals in and out. When the package is molded or encapsulated, the encapsulation materials, such as molding compound, underfill, or mold underfill, can flow over the optical window or grating area, which can block the photonic circuit from properly sending or receiving optical signals. Therefore, a need exists for improved methods of keeping encapsulation materials from a grating surface or optical window of a photonic semiconductor die.

### BRIEF DESCRIPTION OF THE DRAWINGS

FIGS. 1a-1c illustrate a semiconductor wafer with a plurality of photonic semiconductor die separated by a saw street;

FIGS. 2a-2p illustrate forming a semiconductor package with the photonic semiconductor die using ultraviolet light for protection of the photonic circuit;

FIG. 3 illustrates an alternative masking method; and

FIGS. 4a-4c illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

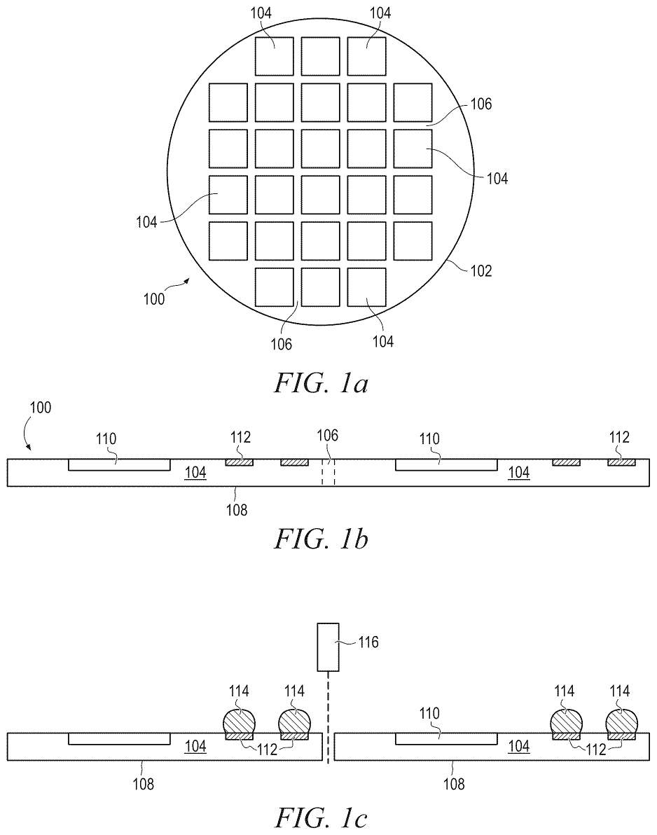

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of photonic semiconductor die 104 is formed on wafer 100 separated by a non-active, inter-die wafer area or saw street 106. Saw street 106 provides cutting areas to singulate semiconductor wafer 100 into individual photonic semiconductor die 104. In one embodiment, semiconductor wafer 100 has a width or diameter of 100-450 millimeters (mm). Wafer 100 can include hundreds or thousands of photonic semiconductor die 104. In some embodiments, photonic semiconductor die 104 is a silicon photonic integrated circuit (PIC), photodetector, or a vertical-external-cavity surface-emitting-laser (VESCEL) component. Other types of photonic semiconductor die are used in other embodiments.

FIG. 1b shows a cross-sectional view of a portion of semiconductor wafer 100. Each photonic semiconductor die 104 has a back or non-active surface 108 and an active surface including a photonic circuit 110 formed within the die. Photonic circuit 110 is an electronic circuit capable of receiving an optical signal and converting the optical signal into an electrical signal for further processing, generate an optical signal based on a received electrical signal, or both. In some embodiments, photonic circuit 110 includes optical circuits that process optical signals directly before or instead of converting them to electrical signals.

The area of, on, or over photonic circuit 110 may be referred to as a grating area because a grating connector is mounted there in some embodiments. The active surface may also include one or more transistors, diodes, and other circuit elements formed within the active surface to implement analog circuits or digital circuits, such as a digital signal processor (DSP), an application specific integrated circuit (ASIC), memory, or other signal processing circuit. Photonic semiconductor die 104 may also contain IPDs, such as inductors, capacitors, and resistors, for RF signal processing.

Wafer 100 is commonly a wafer of photonic semiconductor die 104 delivered by a manufacturer of the wafer to a manufacturer of semiconductor packages that will include the photonic semiconductor die. The manufacturer of wafer 100 has formed an interconnect structure over the active surface including contact pads 112 for external interconnect. The interconnect structure may have one or more layers of conductive traces with insulating layers formed between the layers. The interconnect structure also electrically interconnects photonic circuit 110 and contact pads 112 per the intended functionality of photonic semiconductor die 104.

The conductive layers, including contact pads 112, are formed over wafer 100 using physical vapor deposition (PVD), chemical vapor deposition (CVD), electrolytic plating, electroless plating, or another suitable metal deposition process. The conductive layers can be one or more layers of aluminum (Al), copper (Cu), tin (Sn), nickel (Ni), gold (Au), silver (Ag), or other suitable electrically conductive material. Any conductive layer mentioned above or below can be formed of the same methods and materials. Contact pads 112 include an under-bump metallization (UBM) in some embodiments.

An electrically conductive bump material is deposited over contact pads 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads 112 using a suitable attachment or bonding process. In one embodiment, the bump material is reflowed by heating the material above its melting point to form balls or bumps 114. Contact pads 112 can be, or include, an under-bump metallization (UBM) having a wetting layer, barrier layer, and adhesion layer. Bumps 114 can also be compression bonded or thermocompression bonded to conductive layer 112.

In FIG. 1c, semiconductor wafer 100 is singulated through saw street 106 using a saw blade or laser cutting tool 118 into individual photonic semiconductor die 104. The individual photonic semiconductor die 104 can be inspected and electrically tested for identification of known good die (KGD) or known good unit (KGU) after singulation.

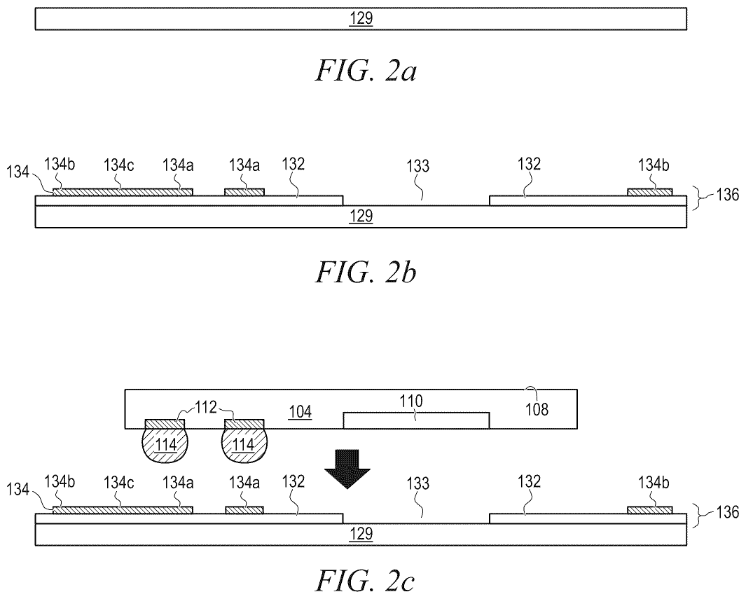

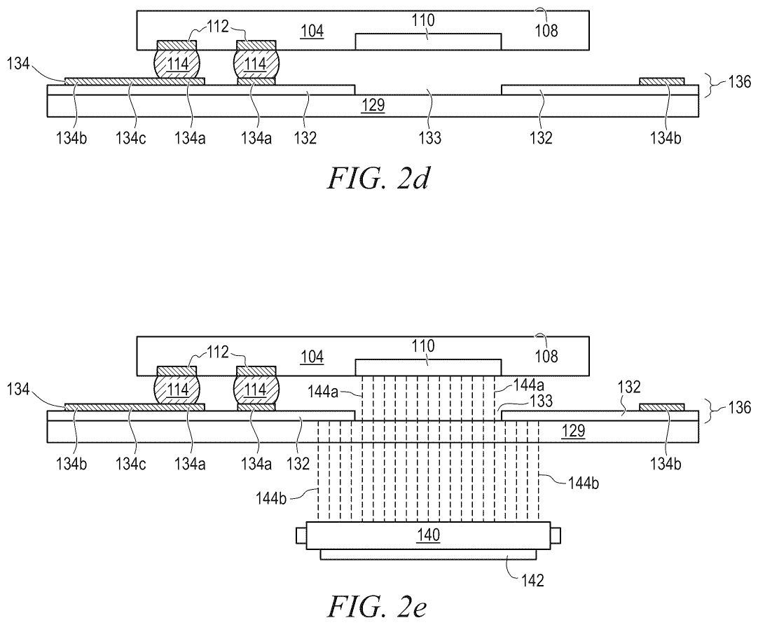

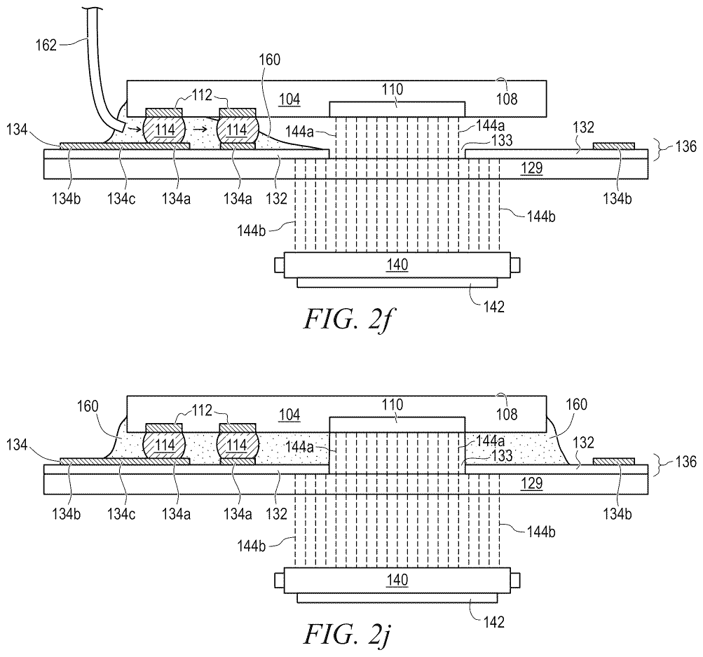

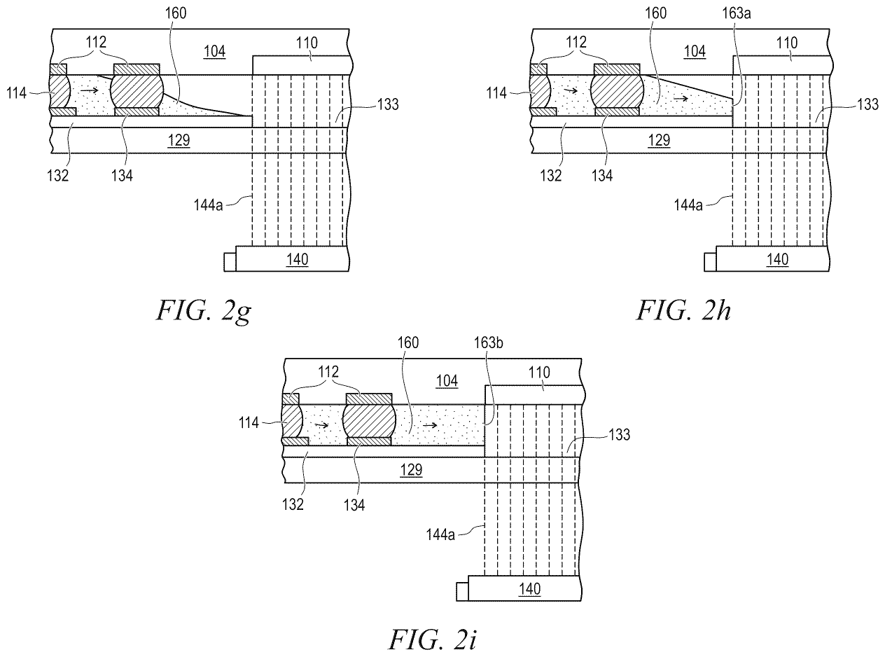

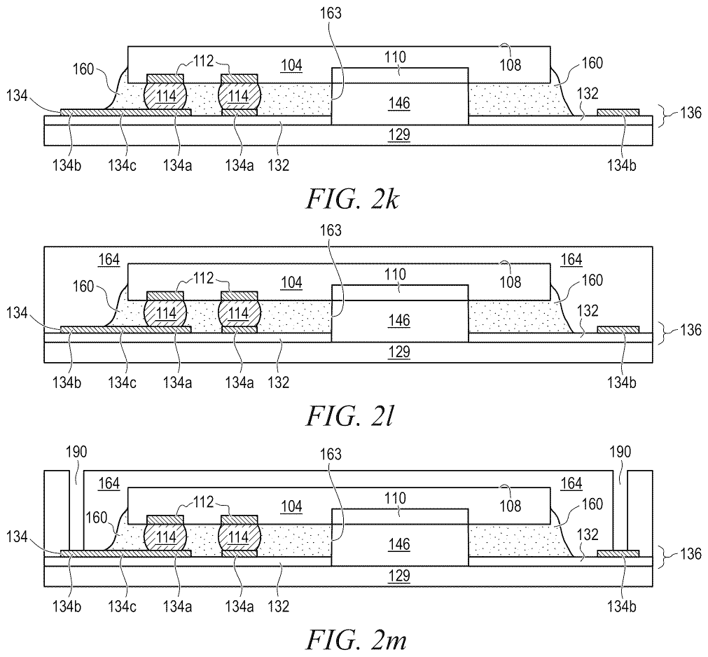

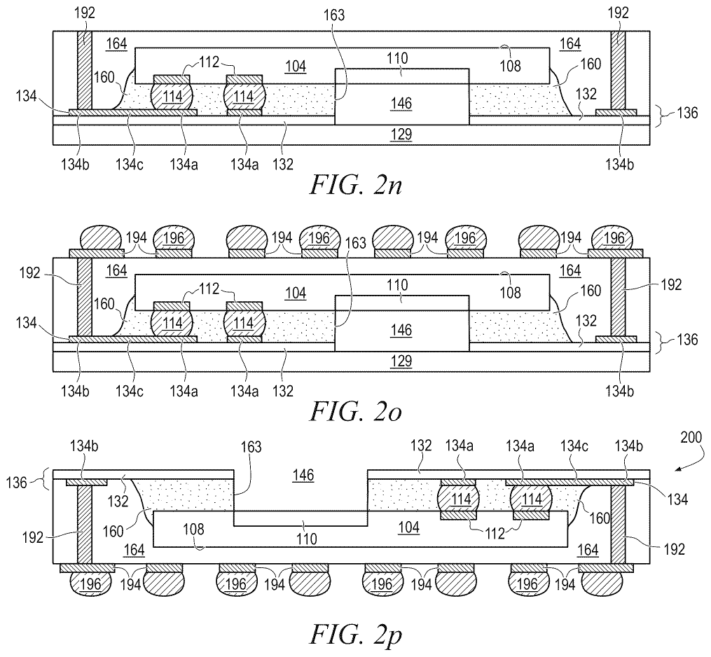

FIGS. 2a-2p illustrate the formation of an optical semiconductor package including a photonic semiconductor die 104. FIG. 2a shows a carrier 129 containing sacrificial base material such as silicon, polymer, beryllium oxide, glass, or other suitable low-cost, rigid material for structural support. In some embodiments, carrier 129 includes an optional interface layer, debonding adhesive layer, or double-sided formed or disposed over the carrier as a temporary adhesive bonding film, etch-stop layer, thermal release layer, or UV release layer. The term carrier can refer to just carrier 129 or the combination of carrier 129 and the optional interface layer. Carrier 129 is formed of a material that is translucent or transmissive of ultraviolet (UV) light. The optional interface layer is likewise UV transmissive or transparent if used.

In FIG. 2b, an insulating or passivation layer 132 is formed on carrier 129. Insulating layer 132 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 132 can be formed using PVD, CVD, printing, lamination, spin coating, spray coating, sintering, or thermal oxidation. Any insulating, passivation, or dielectric layer mentioned above or below can be formed using any of the materials or methods described for insulating layer 132.

An opening 133 is formed through insulating layer 132 using chemical etching, mechanical drilling, laser ablation, photolithography, or another suitable process. Opening 133 is configured such that when photonic semiconductor die 104 is mounted, photonic circuit 110 will be aligned to the opening. Opening 133 will then allow light signals to pass through insulating layer 132 to photonic circuit 110. Additional openings can be formed through insulating layer 132 if needed for subsequent electrical interconnect to the external surface of the final package being formed.

A conductive layer 134 is formed over insulating layer 132. Conductive layer 134 includes contact pads 134a for mounting semiconductor die 104, contact pads 134b for external interconnect, and conductive traces 134c fanning in or out from the contact pads, e.g., to connect contact pads 134a to contact pads 134b. Optionally, conductive layer 134 can include conductive vias extending through insulating layer 132 for subsequent vertical electrical interconnect. In other embodiments, conductive layer 134 is formed on insulating layer 132 without openings in the insulating layer and openings are formed later to expose contact pads of conductive layer 134 for electrical interconnect.

Insulating layer 132 and conductive layer 134 constitute a build-up interconnect structure 136, so called because the interconnect structure is formed by successively building up insulating layers and conductive layers over carrier 129 until the desired signal routing is achieved. While only one conductive layer and one insulating layer are shown, any number of conductive and insulating layers can be interleaved over each other to form build-up interconnect structure 136.

In FIG. 2c, a photonic semiconductor die 104 is picked and placed over build-up interconnect structure 136. Photonic circuit 110 is aligned to opening 133. A footprint of photonic circuit 110 is typically fit completely within a footprint of opening 133, and usually given some margin, to ensure that the photonic circuit can properly operate through the opening. Each solder bump 114 is aligned to a contact pad 134a. When photonic semiconductor die 104 is lowered onto build-up interconnect structure 136, each solder bump 114 rests on conductive layer 134. Conductive layer 112 is electrically and physically coupled to conductive layer 134 by reflowing solder bumps 114 in FIG. 2d. Reflow can be performed by an oven, laser-assisted bonding, or any other suitable means in other embodiments.

In FIG. 2e, a UV lamp 140 is disposed under carrier 129. A reflector 142 is optionally disposed under UV lamp 140 to guide UV light 144 up toward carrier 129. UV lamp 140 is positioned to emit UV light 144 through opening 133 but may be large enough to emit light onto the entirety of the carrier, possibly including a plurality of units being formed together on a single carrier all being within the footprint of the same UV lamp 140.

UV light 144 is transmitted through carrier 129 with relatively little attenuation, absorption, or other modification, while insulating layer 132 blocks the UV light. Therefore, UV light rays 144a extend through opening 133 to impinge on semiconductor die 104 while UV light rays 144b are blocked by insulating layer 132 and do not reach the semiconductor die. While UV light 144 is shown as perfectly vertical between UV lamp 140 and semiconductor die 104, the UV lamp is typically an omnidirectional light source so some photons will travel diagonally into the footprint of insulating layer 132 between semiconductor die 104 and the insulating layer.

In FIG. 2f, an underfill 160 is deposited between build-up interconnect structure 136 and photonic semiconductor die 104 using a dispenser head or nozzle 162. In capillary underfill dispensing, nozzle 162 is a needle or jetting system used to dispense a precise amount of underfill material along one or more edges of semiconductor die 104. The low viscosity of underfill 160 allows it to flow into the gap between semiconductor die 104 and build-up interconnect structure 136 through capillary action, spreading evenly beneath semiconductor die 104 to encapsulate solder bumps 134a. Other underfill deposition methods are used in other embodiments.

Underfill 160 is a photobond acrylate, a type of acrylate adhesive that cures when exposed to UV light 144. Underfill 160 remains liquid until activated by UV light 144, at which point the underfill polymerizes and forms a solid. In one embodiment, underfill 160 is activated under a UV light 144 at 366 nanometers (nm) wavelength and room temperature. Other frequencies are used in other embodiments, depending on the specific photobond acrylate material being used.

Underfill 160 flows into the space between build-up interconnect structure 136 and photonic semiconductor die 104 to fill the space and provide structural support. In FIG. 2f, underfill 160 is being filled in from the left edge of semiconductor die 104 and flowing to the right toward opening 133. FIG. 2g shows a close-up view of underfill 160 as the underfill approaches opening 133.

In FIG. 2h, underfill 160 continues to flow toward opening 133. However, as underfill 160 reaches opening 133, the underfill is cured by UV light 144. Rather than flow into opening 133, underfill 160 builds up at the edge of insulating layer 132 to form a vertical edge 163a of the underfill. In FIG. 2i, underfill 160 has continued to flow to the point that the gap between semiconductor die 104 and insulating layer 132 is completely filled with a vertical surface 163b that extends continuously from the semiconductor die to the insulating layer. The flow of underfill 160 is slow enough that the underfill cures before flowing into opening 133.

The cure time of underfill 160 is typically two seconds or less. In other embodiments, longer cure times are used. While underfill 160 is shown as flowing along the surface of insulating layer 132, the actual shape of the leading underfill edge may be a rounded surface flowing along surfaces of semiconductor die 104 and insulating layer 132 in parallel and at approximately the same rate with a rounded leading surface. Underfill 160 can flow in any shape and still be cured at the edge of opening 133 as illustrated. While underfill 160 is shown as stopping exactly at the edge of opening 133 without extending into the opening, the underfill may flow into the opening and onto carrier 129 slightly in some embodiments where the cure time allows for such a situation. Photonic circuit 110 is given enough of a margin within the footprint of opening 133 that any flow of underfill 160 into opening 133 will not harm the operation of the photonic circuit. Surface 163 is considered at the edge of opening 133 as long as the opening is used as a mask to cure underfill 160, whether or not the underfill flows into the opening.

While side surface 163 of underfill 160 is shown as being perfectly vertical, the actual shape can vary. Side surface 163 may lean in over opening 133 due to underfill flowing slightly into the opening before being cured. Side surface 163 may also lean out away from opening 133 due to UV light 144 not being perfectly vertically aligned, and thereby going between insulating layer 132 and semiconductor die 104 outside of the opening. The cured inner surface 163 may also be a concave or convex curve, or other arbitrary shapes. The side surface 163 can be considered vertical even if it has non-verticality due only to the speed of curing, the angle of UV light 144, or other logistical considerations related to the flow of underfill 160.

FIG. 2j illustrates underfill 160 after fully dispensing the underfill such that the space between semiconductor die 104 and build-up interconnect structure 136 is completely filled outside of a perimeter of opening 133. Underfill 160 may be dispensed along all four edges of semiconductor die 104 to ensure that the underfill reaches all four sides of opening 133, such that vertical surface 163 extends continuously and completely around opening 133. UV lamp 140 remains on until the underfill is completely dispensed. Underfill 160 is cured at the edge of opening 133 regardless of the direction from which the underfill is flowing. FIG. 2k shows underfill 160 after curing with lamp 140 being turned off or removed.

In FIG. 2l, an encapsulant or molding compound 164 is deposited over and around photonic semiconductor die 104 and build-up interconnect structure 136 using a paste printing, compression molding, transfer molding, liquid encapsulant molding, vacuum lamination, spin coating, or other suitable applicator. Encapsulant 164 can be liquid or granular polymer composite material, such as epoxy resin, epoxy acrylate, or another suitable polymer, with or without a filler. Encapsulant 164 is non-conductive, provides structural support, and environmentally protects the semiconductor device from external elements and contaminants. In some embodiments, underfill 160 is not used, and molding compound 164 is a photobond acrylate that is cured as it flows between build-up interconnect structure 136 and semiconductor die 104 and reaches opening 133.

In FIG. 2m openings or vias 190 are formed through encapsulant 164 down to conductive layer 134. Vias 190 are formed by chemical etching, laser etching, mechanical drilling, or another suitable means. Vias 190 expose contact pads 134a for subsequent electrical interconnect. In FIG. 2n, vias 190 are filled with conductive material to form conductive vias 192. Conductive vias 192 are formed by any suitable conductive material deposition means, such as those discussed above for other conductive layers. Conductive vias 192 can be formed of any suitable conductive material, such as those discussed above for conductive layers generally, e.g., copper. Top surfaces of conductive vias 192 are made coplanar to the top surface of encapsulant 164 by backgrinding in some embodiments.

In FIG. 2o, conductive layer 194 and solder bumps 196 are formed on the back surface of encapsulant 164. Conductive layer 194 is formed using methods and materials mentioned above for other conductive layers and is patterned to fan-in electrical connection from conductive vias 192 to solder bumps 196. Bumps 196 are formed on contact pads of conductive layer 194 using the same methods and materials discussed above for solder bumps 114.

Bump 196 represents one type of interconnect structure that can be formed over conductive layer 194. The interconnect structure can also use bond wires, conductive paste, stud bump, micro bump, land grid array, or other electrical interconnect. In one embodiment, conductive vias 190, conductive layer 194, and solder bumps 196 are not formed, and the package being formed is mounted to another larger substrate of an end device directly through build-up interconnect structure 136. Build-up interconnect structure 136 can be mounted to a larger PCB using flip-chip mounting with photonic circuit 110 oriented toward the PCB or using bond wires with the photonic circuit oriented away from the PCB.

FIG. 2p illustrates carrier 129 removed by thermal, UV, or other release. A semiconductor package 200 is completed by singulating encapsulant 164 and build-up interconnect structure 136 if necessary to separate a panel of packages from each other. Area 146 remains free of underfill 160 and encapsulant 164 so that photonic circuit 110 is exposed from package 200. In some embodiments, a fiber optic connector is mounted in area 146 as part of the packaging process. In other embodiments, area 146 remains open as illustrated and a fiber optic connector or bare fiber is glued into area 146 as part of the process of installing package 200 into an end device. Alternatively, a lens can be glued into or over area 146 during packaging or later.

Package 200 includes a photonic semiconductor die 104 with a photonic circuit 110 that remains free of interference from underfill 160 or encapsulant 164 by UV curing of the underfill through opening 133 of insulating layer 132. Build-up interconnect structure 136 acts as a mask to control the area that UV light 144 reaches underfill 160 to prevent underfill bleeding over photonic circuit 110. Underfill 160 stops where UV light 144 shines through opening 133. Utilizing UV light 144 to stop the flow of underfill 160 reduces the burden of a separate physical dam having to be manufactured. The process margin for flip-chip attachment is improved by preventing cold joints.

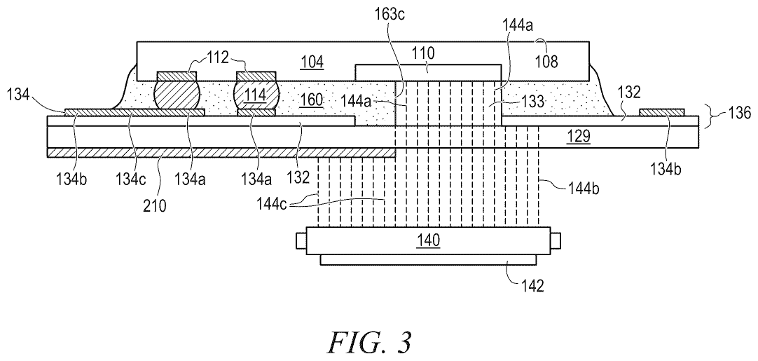

Another advantage of the use of UV light to prevent underfill bleeding is the flexibility to change the flow stop area of interest by changing the mask or adding a new mask. FIG. 3 illustrates a tape 210 attached onto the bottom surface of carrier 129, opposite semiconductor die 104. Tape 210 masks off an additional portion of opening 133 so that UV light 144c is masked by tape 210. Underfill 160 flows into opening 133 up to the edge of tape 210, instead of stopping at the edge of opening 133 as shown above. A side surface 163c of underfill 160 is formed at or over the edge of tape 210. Tape 210 or another structure under carrier 129 can be used to modify the masked area after semiconductor die 104 is flip-chip mounted. In contrast, the prior art typically uses a dam structure between carrier 129 and semiconductor die 104 to block the flow of underfill 160, which means that the area to be blocked from the flow of underfill 160 is not modifiable after flip-chip mounting.

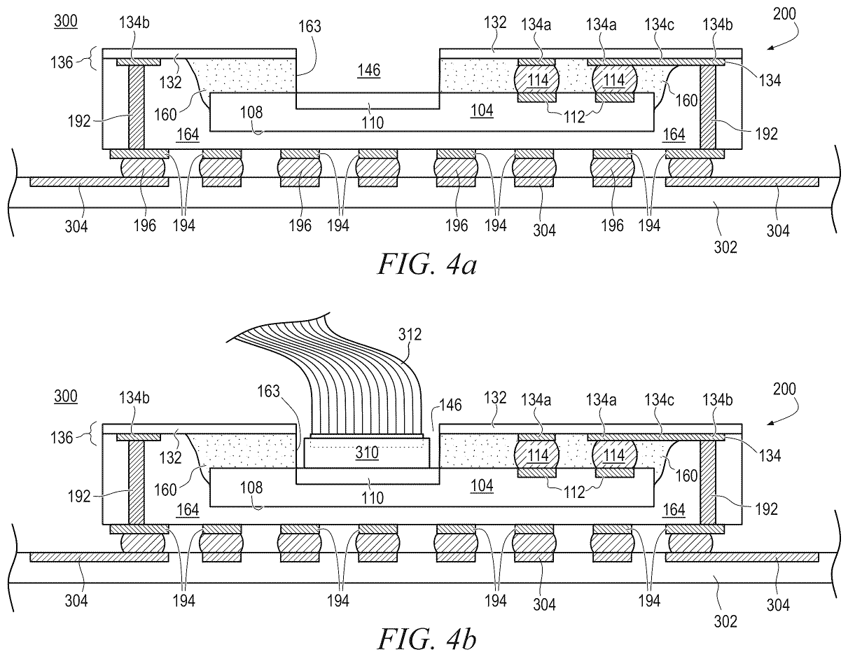

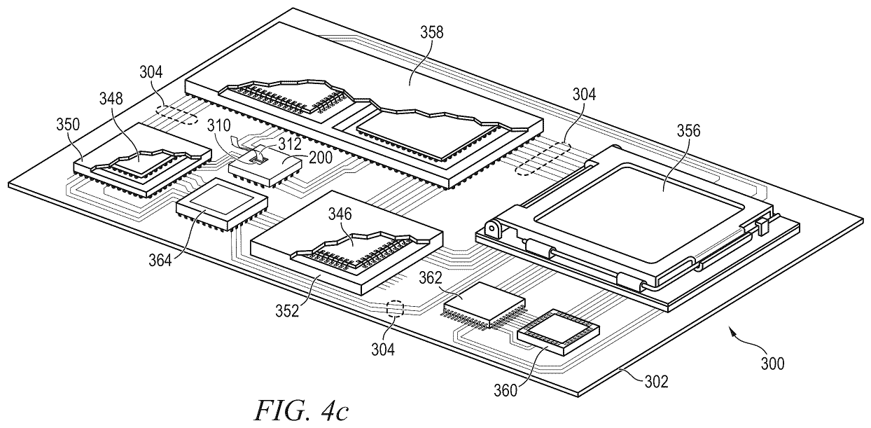

FIGS. 4a-4c illustrate integrating the above-described semiconductor packages, e.g., semiconductor package 200, into a larger electronic device 300. FIG. 4a illustrates a partial cross-section of semiconductor package 200 mounted onto a printed circuit board (PCB) or other substrate 302 as part of electronic device 300. Solder bumps 196 are reflowed onto conductive layer 304 of PCB 302 to physically attach and electrically connect semiconductor package 200 to the PCB. In other embodiments, thermocompression or another suitable attachment and connection methods are used. In some embodiments, an adhesive or underfill layer is used between semiconductor package 200 and PCB 302. Photonic semiconductor die 104 is electrically coupled to conductive layer 304 through bumps 196, conductive layer 194, conductive vias 192, conductive layer 134, and solder bumps 114.

In FIG. 4b, a fiber array unit (FAU) 310 is mounted onto a grating area of photonic circuit 110. FAU 310 is attached to photonic circuit 110 using a layer of optical adhesive. FAU 310 includes one or more fiber optic cables 312 bundled together for transmitting and receiving optical signals to or from semiconductor die 104. Fiber optic cables 312 can be attached to package 200 using any suitable coupler. In other embodiments, photonic circuit 110 transmits or receives an optical signal without a fiber optic cable being attached.

FIG. 4c illustrates electronic device 300 having a chip carrier substrate or PCB 302 with a plurality of semiconductor packages disposed on a surface of PCB 302, including semiconductor package 200. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 4c, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a transparent carrier;
forming a build-up interconnect structure on the transparent carrier;
forming an opening through the build-up interconnect structure;
disposing semiconductor die over the build-up interconnect structure with a photonic circuit of the semiconductor die aligned to the opening;
disposing an ultraviolet (UV) lamp over the carrier opposite the semiconductor die, wherein the UV lamp emits a UV light that impinges on the photonic circuit through the carrier and opening; and
depositing an underfill between the build-up interconnect structure and semiconductor die while the UV lamp emits the UV light.

2. The method of claim 1, further including depositing the underfill sufficiently to flow to the opening, wherein the UV light cures the underfill before the underfill flows into the opening.

3. The method of claim 1, further including disposing a solder bump between the semiconductor die and build-up interconnect structure.

4. The method of claim 1, further including disposing a tape on the carrier opposite the semiconductor die and over the opening.

5. The method of claim 1, further including depositing the underfill to surround the opening.

6. The method of claim 1, further including mounting a fiber array unit (FAU) onto the photonic circuit.

7. A method of making a semiconductor device, comprising:
providing a semiconductor die including a photonic circuit;
forming an insulating layer;
forming an opening through the insulating layer;
disposing the semiconductor die over the insulating layer with the photonic circuit aligned to the opening;
disposing an ultraviolet (UV) lamp over the photonic circuit, wherein the UV lamp emits a UV light that impinges on the photonic circuit through the opening; and
depositing an underfill between the insulating layer and semiconductor die while the UV lamp emits the UV light.

8. The method of claim 7, further including depositing the underfill sufficiently to flow to the opening, wherein the UV light cures the underfill at an edge of the opening.

9. The method of claim 7, further including depositing the underfill to surround the opening.

10. The method of claim 7, further including disposing a tape over the insulating layer opposite the semiconductor die, wherein the insulating layer and tape in combination mask the UV light.

11. The method of claim 7, further including mounting a fiber array unit (FAU) onto the photonic circuit.

12. The method of claim 7, further including:
forming a conductive layer over the insulating layer; and
depositing the underfill between the conductive layer and semiconductor die.

13. The method of claim 12, further including disposing a solder bump between the semiconductor die and conductive layer.

14. A method of making a semiconductor device, comprising:
forming an insulating layer;
forming an opening through the insulating layer;
emitting a UV light through the opening; and
depositing a photobond acrylate over the insulating layer, wherein the UV light cures the photobond acrylate using the insulating layer as a mask.

15. The method of claim 14, wherein the UV light cures the photobond acrylate before the photobond acrylate flows into the opening.

16. The method of claim 14, further including disposing a photonic semiconductor die over the insulating layer with a photonic circuit of the photonic semiconductor die aligned to the opening.

17. The method of claim 16, further including depositing the photobond acrylate between the insulating layer and photonic semiconductor die.

18. The method of claim 16, further including mounting a fiber array unit (FAU) onto the photonic circuit.

19. The method of claim 14, further including disposing a tape over the insulating layer, wherein the insulating layer and tape in combination mask the UV light.

20. The method of claim 14, further including depositing the photobond acrylate to surround the opening.

21. A semiconductor device, comprising:
a semiconductor die including a photonic circuit;
an insulating layer formed over the semiconductor die with an opening in the insulating layer aligned to the photonic circuit;
a photobond acrylate disposed between the insulating layer and semiconductor die, wherein the photobond acrylate includes vertical surface extending from the semiconductor die to the insulating layer at an edge of the opening; and
an ultraviolet lamp disposed over the insulating layer opposite the semiconductor die.

22. The semiconductor device of claim 21, further including a tape disposed over the insulating layer and extending over the opening.

23. The semiconductor device of claim 21, further including a fiber array unit (FAU) disposed over the photonic circuit.

24. The semiconductor device of claim 21, wherein the vertical surface of the photobond acrylate extends continuously and completely around the photonic circuit in plan view.

25. The semiconductor device of claim 21, wherein the insulating layer is formed on a transparent carrier.
